(19) United States
(12) Patent Application Publication
(10) Pub. No.: US 2004/0076744 A1
(43) Pub. Date: Apr. 22, 2004

(54) Method for forming solder-resist film

(76) Inventors: Keiichi Okajima, Osaka-city (JP); Hiroshi Oda, Toyonaka-city (JP); Takahiro Nakano, Ibaraki-city (JP)

Correspondence Address: LAW OFFICES OF TOWNSEND & BANTA, Suite 900, South Building, 601 Pennsylvania Ave., N.W., Washington, DC, 20004, US

(21) Appl. No.: 10/630,858

(22) Filed: Jul. 31, 2003

(30) Foreign Application Priority Data
Aug. 1, 2002 (JP) 224827/2002

(51) Int. Cl. H05K 1/11; B05D 5/12

(52) U.S. Cl. 427/96

(57) ABSTRACT

The method of the present invention is a method for forming a solder-resist film on a circuit board having patterned circuit conductor parts at least on one face and involves steps of forming a resin layer between neighboring circuit conductor parts by applying a liquid-phase curable resin so as to fill grooves between the neighboring circuit conductor parts and forming a solder-resist film by applying a solder resist to the circuit board having the resin layer.

### BACKGROUND OF THE INVENTION

1. Field of the Invention

The present invention relates to a method for forming a solder-resist film on a circuit board of such as a printed wiring board.

2. Related Art

As a method for mounting parts in a circuit board of such as a printed wiring board is generally employed a method by soldering and a solder is previously applied to the points where parts are to be mounted and the parts are mounted by melting the solder at the time of mounting of the parts. A method for forming patterns of a solder-resist film on a circuit board of such as a printed wiring board is generally employed as the method for previously applying a solder to predetermined points. The solder-resist film is useful for applying a solder only to the points where no pattern of the film is formed, preventing application of the solder to the points where patterns of the film are formed, and protecting the circuit in the points where the patterns are formed.

Mounting of parts on a circuit board has been highly densified in recent years and patterns of a solder-resist film have been required to be finer. Therefore, a method for patterning a solder resist by photolithographic technique is generally employed and a photosensitive resin composition is generally used as the solder resist. As a method for patterning is employed a method involving applying a liquid-phase photoresist composition diluted with an organic solvent or the like by a spraying coating, roll coater coating, or curtain coater coating method for forming a coating film and then patterning the coating film by the photolithographic technique.

With respect to a printed wiring board to be employed for an electric system of automobiles or the like, investigations have been made to bundle a large number of wiring wires to make them compact and therefore, a large quantity of electric current is required to flow in a printed wiring board. As a result, it has been tried to make the thickness of circuit conductor parts in the printed wiring board thick.

However, if the thickness of the circuit conductor parts is made thick, when a solder-resist film is formed, there occurs a problem that edge parts of the circuit conductor parts cannot be sufficiently coated with the solder-resist film.

FIG. 3 is a cross-sectional view for illustrating the above-mentioned problem. As illustrated in FIG. 3, a solder-resist film 3 is formed on circuit conductor parts 2 of a circuit board 1. Since the thickness of the circuit conductor parts 2 is as thick as 100 μm or thicker, the thickness of the solder-resist film 3 becomes thin in the vicinity of the edge parts 2a of the circuit conductor parts 2 and the solder-resist film 3 does not sufficiently cover the vicinity of the edge parts 2a. Accordingly, there is a risk to cause electric short circuit in the edge parts 2a of the circuit conductor parts 2 and there occurs a problem that sufficient insulation cannot be attained.

### SUMMARY OF THE INVENTION

The purpose of the present invention is to provide a solder-resist film formation method capable of forming an excellent solder-resist film even on a circuit board of which the circuit conductor parts are thick.

A first aspect of the present invention is a method for forming a solder-resist film on a circuit board having patterned circuit conductor parts at least on one face and involving steps of forming a resin layer between neighboring circuit conductor parts by applying a liquid-phase curable resin so as to fill grooves between the neighboring circuit conductor parts and forming a solder-resist film by applying a solder resist to the circuit board having the resin layer.

According to the first aspect of the present invention, the resin layer is formed so as to fill the grooves between the neighboring circuit conductor parts by at first applying a liquid-phase curable resin. After filling the grooves between the neighboring circuit conductor parts with the liquid-phase curable resin, a solder resist is applied to form a solder-resist film. Since the steps in the edge parts of the circuit conductor parts are lowered by filling the grooves between the neighboring circuit conductor parts with the liquid-phase curable resin, the edge parts of the circuit conductor parts can be well coated with the solder-resist film.

With respect to the first aspect of the present invention, the step of forming the resin layer using the liquid-phase curable resin preferably involves a step of forming a resin layer by applying the liquid-phase curable resin and then curing the resin and a step of removing the resin layer remaining on the circuit conductor parts by polishing the surface of the circuit board.

Further, the resin layer to be formed on the circuit conductor parts can be lessened by removing the liquid-phase curable resin adhering to the top parts of the circuit conductor parts by, for example, squeezing before curing the liquid-phase curable resin. Therefore, such a step may be added further.

The surface of the circuit board is polished by, for example, buffing to remove the resin layer remaining on the top parts of the circuit conductor parts. Since the solder-resist film is to be formed on the circuit conductor parts, in the case the resin layer of the liquid-phase curable resin is formed, it is preferable to remove the resin layer.

A second aspect of the present invention is a method for forming a solder-resist film on a circuit board having patterned circuit conductor parts at least on one face and involving steps of forming a resin layer by applying a liquid-phase curable resin to a circuit board in a state that an etching resist film used for patterning remains on circuit conductor parts so as to fill grooves between the neighboring circuit conductor parts and curing the liquid-phase curable resin; removing the etching resist film remaining on the surface of the circuit conductor parts together with the resin layer; and forming a solder-resist film by applying a solder resist to the circuit board.

According to the second aspect of the present invention, in the state that the etching resist film used for patterning is left on the circuit conductor parts, the resin layer of the liquid-phase curable resin is formed in the grooves between the neighboring circuit conductor parts by applying the liquid-phase curable resin and after that, the etching resist film remaining on the surface of the circuit conductor parts and the resin layer of the liquid-phase curable resin formed thereon can be simultaneously removed.

Also with respect to the second aspect of the present invention, being similar to the first aspect, after the resin film is formed between neighboring circuit conductor parts by applying the liquid-phase curable resin so as to fill the grooves between the neighboring circuit conductor parts, the solder-resist film is formed by applying the solder resist. Accordingly, since the solder-resist film is formed in the state that the steps in the edge parts of the circuit conductor parts are lowered, the edge parts of the circuit conductor parts can be well coated with the solder-resist film.

Hereinafter, common respects of the first and the second aspects of the present invention will be described, referring to as “the present invention”.

With respect to the present invention, in order to fill grooves between circuit conductor parts, a liquid-phase curable resin is applied. The liquid-phase curable resin to be employed for the present invention is a curable resin such as a thermosetting resin, a UV curable resin and the like and having an insulating property. The liquid-phase curable resin of the present invention is a liquid-phase liquid having fluidity to apply it so as to fill the grooves between the neighboring circuit conductor parts by a squeegee printing method such as a screen printing method or a roll-rolling method. Especially, a paste type resin having structural viscosity is preferable. Such a paste type resin having the structural viscosity is excellent in a filling and coating property since fluidity is generated by high shearing force by a squeegee and the structural viscosity is exhibited after filling the grooves to hardly drip the resin.

A method for applying the liquid-phase curable resin so as to fill the above-mentioned grooves may be, as described above, carried out by the squeegee printing method using a screen printing plate or roll-rolling method and as a further preferable and easy method is exemplified a method for filling the grooves between the neighboring circuit conductor parts by applying the liquid-phase curable resin to the circuit board by squeezing the resin by using only a squeegee without using a printing plate.

Components of the liquid-phase curable resin to be employed for the present invention are not particularly limited, epoxy type resins are especially preferable to be used. The epoxy type resins are preferable in terms of small curing shrinkage and reliability. The epoxy type resins to be employed may include, for example, bisphenol type epoxy resins, phenol type epoxy resins, cresol type epoxy resins, and the like. These resins may be mixed with a catalyst for curing by heat or UV rays, a filler, a defoaming agent, and the like.

In the present invention, after the liquid-phase curable resin is applied, in the case the liquid-phase curable resin adheres to the top parts of the circuit conductor parts, the liquid-phase curable resin on the top parts of the circuit conductor parts is preferable to be removed by, for example, squeezing. That is for preventing formation of unnecessary resin layer of the liquid-phase curable resin in order to form a solder-resist film on the circuit conductor parts by applying a solder resist.

In the present invention, after the liquid-phase curable resin is applied, the liquid-phase curable resin is cured by heating or UV radiation to form the resin layer.

After the resin layer is formed, as described above, it is preferable to remove the resin layer remaining on the circuit conductor parts by polishing the surface of the circuit conductor parts by, for example, buffing. Further, in the second aspect, at the time of removing the etching resist film used for patterning the circuit conductor parts, the resin layer formed thereon can be removed.

In the present invention, next, a solder resist is applied to the circuit board in which the grooves between the neighboring circuit conductor parts are filled with the resin layer. After being applied, the solder resist is dried, exposed to active energy beam such as UV rays, and developed with an alkaline washing solution for removing the un-exposed parts and patterning the solder resist. After the patterning, the exposed parts are cured by heating to form a solder-resist film. Further, in place of such a patterning method, a solder-resist film may be formed by applying the solder resist in patterns by using a screen printing plate in which the patterns are previously formed at the time of applying the solder resist and curing the solder resist by heating.

The solder resist to be used in the present invention may be a photosolder resist requiring photocuring and developing steps or a thermosetting type ink. In the case of using such a thermosetting type ink, an application method for forming patterns in the step of application by screen printing method or the like as described above.

As a resin composition to be used for the photosolder resist is usable, for example, a water-based photosolder resist composition disclosed in Japanese Patent Laid-Open No. 222103(2001). The photosolder resist composition contains (A) an aqueous solution obtained by neutralizing a resin containing radical polymerizable groups and carboxyl groups with a base; (B) an inorganic filler; (C) a multi-functional acrylic monomer (c1), a compound having a cyclic ether group (c2), and a photopolymerization initiator (c3); and (D) an aqueous solution obtained by neutralizing a radical polymer having an acid value of 30 to 230 mg KOH/g with a base based on the necessity.

Materials to be used for the thermosetting type ink are not particularly limited, however in many cases, they include an epoxy resin and its curing agent and further inorganic pigments or organic pigments as fillers.

According to the present invention, after the grooves between the neighboring circuit conductor parts are filled with the resin layer, the solder-resist film is formed by applying the solder resist. Therefore, even if the thickness of the circuit conductor parts becomes thick, the steps in the edge parts of the circuit conductor parts are lowered by the resin layer, the edge parts of the circuit conductor parts can be well coated with the solder-resist film.

### BRIEF DESCRIPTION OF THE DRAWINGS

FIG. 1 shows a cross-sectional view illustrating the production steps of an embodiment according to the first aspect of the present invention.

FIG. 2 shows a cross-sectional view illustrating the production steps of an embodiment according to the second aspect of the present invention.

FIG. 3 shows a cross-sectional view illustrating the state of a solder-resist film of a conventional Example.

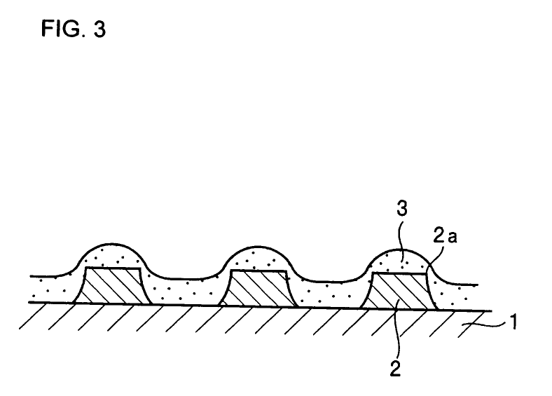

### DESCRIPTION OF THE PREFERRED EMBODIMENTS

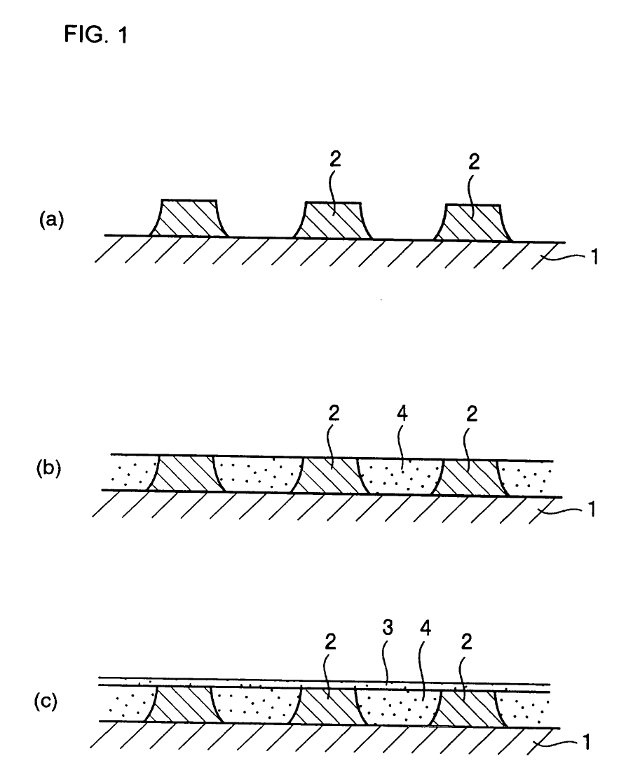

FIG. 1 shows a cross-sectional view illustrating the production steps of an embodiment according to the first aspect of the present invention. As shown in FIG. 1(a), circuit conductor parts 2 are formed on one face of a circuit board 1. The circuit conductor parts 2 are patterned and formed only to necessary parts.

As shown in FIG. 1(b), a liquid-phase curable resin 4 is applied so as to fill grooves between the neighboring circuit conductor parts 2. For example, the liquid-phase curable resin 4 is applied using a screen plate specially made for its use in which regions corresponding to the circuit conductor parts 2 are masked. Use of such a screen plate, the liquid-phase curable resin can be selectively applied only to the grooves between the neighboring circuit conductor parts 2. Further, as described above, without using the screen plate, the liquid-phase curable resin 4 can be applied to the grooves between the neighboring circuit conductor parts 2 by squeezing the liquid-phase curable resin 4 on the circuit board 1 using only a squeegee.

Next, the liquid-phase curable resin 4 is cured to form the resin layer 4 between the neighboring circuit conductor parts 2. In the case a thermosetting resin is used for the liquid-phase curable resin, the resin can be cured by heating and in the case a UV-curable resin is used for the liquid-phase curable resin, the resin can be cured by UV radiation.

Next, in the case a resin layer exists on the top parts of the circuit conductor parts 2 owing to adhesion of the liquid-phase curable resin to the top parts, the surface of the circuit board 1 is preferably polished to remove such a resin layer.

Next, as shown in FIG. 1(c), a solder resist is applied to the circuit board 1 to form a solder-resist film 3. Since the solder-resist film 3 has photosensitivity, patterning is carried out by exposing the film to an active energy beam such as UV rays and developing and removing the unexposed parts with an alkaline washing solution. The photocurable parts are heated and cured to form the solder-resist film 5. Generally, patterning is carried out so as to remove portions of the solder-resist film 5 on the circuit conductor parts 2 where a solder is to be applied. Further, as described above, the solder resist may be applied using a previously patterned screen printing plate and then cured only by heating to form the solder-resist film. In this case, the solder resist may not contain the photocurable components.

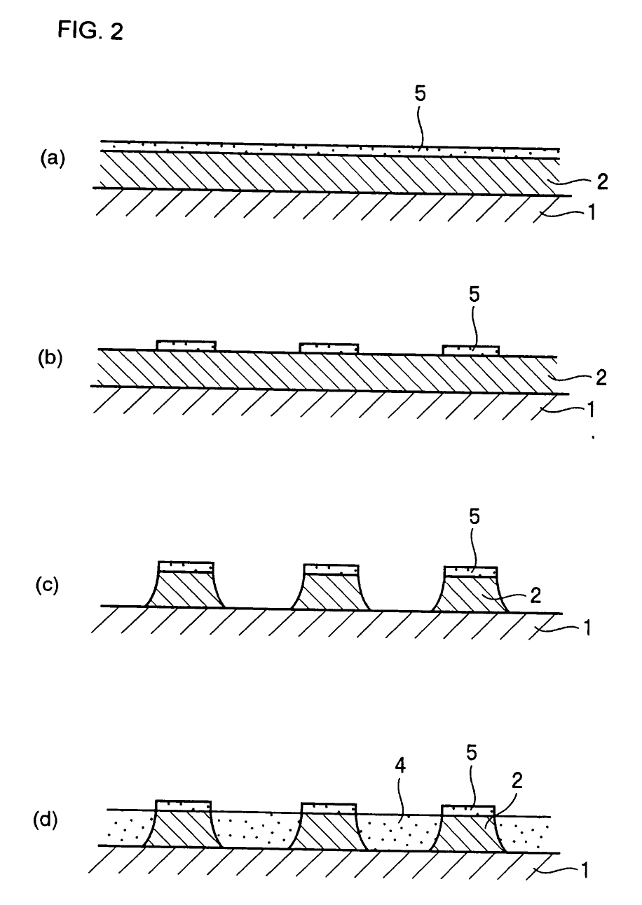

FIG. 2 shows a cross-sectional view illustrating the production steps of an embodiment according to the second aspect of the present invention.

FIG. 2(a) shows the state of a circuit board 1 before patterning of a circuit conductor part 2 and shows, for example, a copper-clad laminate board. In such a state, a photosensitive dry film 5 is stuck to the circuit conductor part 2. The photosensitive dry film 5 is exposed in predetermined patterns and developed to form predetermined patterns of the photosensitive dry film 5 as shown in FIG. 2(b).

Next, using the photosensitive dry film 5 as a mask, the circuit conductor part 2 is etched to carry out patterning of the circuit conductor part as shown in FIG. 2(c). Next, usually, the photosensitive dry film (etching resist film) 5 on the circuit conductor parts 2 is to be removed, however in the aspect of the present invention, a liquid-phase curable resin is applied while the etching resist film 5 being left on the circuit conductor parts 2.

FIG. 2(d) shows the state that the liquid-phase curable resin 4 is applied. In the case the liquid-phase curable resin adheres to the etching resist film 5, the adhering liquid-phase curable resin is preferably removed by squeezing. Next, the liquid-phase curable resin is cured to form a resin layer 4. In the case the liquid-phase curable resin is a thermosetting resin, it is cured by heating and in the case the liquid-phase curable resin is a UV curable resin, it is cured by UV radiation.

After that, the etching resist film 5 on the circuit conductor parts 2 is removed by peeling with an alkaline solution. In the case the resin layer adheres to the etching resist layer 5, the resin layer can be also removed.

Next, in the same manner as the embodiment illustrated in FIG. 1, a solder-resist film can be formed by applying a solder resist.

According to the present invention, since the grooves between the neighboring circuit conductor parts 2 are filled with the resin layer 4, the steps in the edge parts of the circuit conductor parts 2 are lowered. Accordingly, the solder-resist film 3 with an even film thickness can be formed and the edge parts of the circuit conductor parts 2 can be well coated.

### EXAMPLES

[Preparation of Liquid-phase Curable Resin]

As a liquid-phase curable resin, a thermosetting type resin was prepared as follows.

After the following components were preliminarily mixed, they were kneaded and dispersed by three rolls to obtain the thermosetting resin.

| | | |
|---|---|---|
| Epikote 828 | 100 | parts |
| (bisphenol A type epoxy resin, produced by Japan | | by weight |
| Epoxy Resin Co.) | | |
| Curesol 2MZ-A | 9 | parts |
| (imidazole, produced by Shikoku Chemicals Corp.) | | by weight |
| Cristalite WX | | 85 parts |
| (silica, produced by Tatsumori Ltd.) | | by weight |
| AEROSIL R-812 | 2 | parts |
| (fumed silica, produced by Nippon Aerosil Co.) | | by weight |

[Preparation of Water-Based Solder Resist]

A water-based solder resist was prepared as follows.

A 2L separable flask equipped with a refluxing tube, a temperature adjusting unit, and stirring blades was loaded with propyleneglycol monomethyl ether 760 parts by weight and the temperature was adjusted to be 110° C. Here, a liquid mixture containing styrene 170 parts by weight, tert-butyl methacrylate 30 parts by weight, methacrylic acid 300 parts by weight, and tert-butyl peroxy-2-ethylhexanoate 17.5 parts by weight was dropwise titrated for 2 hours and the reaction was continued further for 1 hour. Next, a liquid mixture containing propyleneglycol monomethyl ether 50 parts by weight and tert-butyl peroxy-2-ethylhexanoate 0.75 parts by weight was dropwise titrated for 30 minutes and the reaction was continued further for 1 hour and the temperature was raised to 120° C. and kept for 3 hours. Further, to the resulting reaction system, a mixture of glycidyl methacrylate 300 parts by weight, benzyldimethylamine 1.5 parts by weight, and hydroquinone 1.5 parts by weight was added and reaction was continued for 8 hours under air current. The weight average molecular weight of the obtained resin was 14,700 and the acid value was 96.9 mg KOH/g. The quantity of double bonds was 2.61×10⁻³ mol/g.

The obtained resin solution 200 g was mixed with triethylamine 20 g and ion-exchange water 600 g and stirred for 1 hour and the solvents and a portion of water were removed by pressure reduction to obtain an aqueous solution with a solid matter content of 30.0% by weight.

The obtained aqueous solution (A) 930 parts by weight (solid matter weight 276 parts by weight) was mixed with

B-30 (barium sulfate, produced by Sakai Chemical Industry Co., Ltd.) 250 parts by weight,

Lionol Green 8200 (green color pigment, produced by Toyo Ink Manufacturing Co., Ltd.) 5.0 parts by weight, and

ion-exchange water 795 parts by weight and dispersed in the presence of glass beads by using a sand grinder.

A mixture containing

Epoleed GT-401 25 parts by weight (alicyclic epoxy resin, obtained by ring-opening addition of ε-caprolactone to butanetetracarboxylic acid and terminating the reaction product with alicyclic epoxy groups, produced by Daicel Chem. Ind., Ltd.),

Irgacure 907 8.0 parts by weight (a photopolymerization initiator, produced by Ciba-Geigy Corp.)

Diethylthioxanthone 0.5 part by weight (a photopolymerization initiator, produced by Nippon Kayaku Co., Ltd.),

trimethylolpropane trimethacrylate 11.5 parts by weight, and

propyleneglycol monomethyl ether acetate 10.0 parts by weight,

was added to the dispersion obtained in such a manner 324.1 parts by weight (solid matter weight 106 parts by weight) while being stirred for 20 minutes and the stirring was continued further for 20 minutes to obtain a water-based photosolder resist composition.

### Example 1

For a printed wiring board having 400 μm thickness of circuit conductor parts, the above-mentioned thermosetting resin was applied to grooves between the neighboring circuit conductor parts by the methods illustrated in FIG. 1. The application was carried out by a screen-printing method and the resin was heated at 150° C. for 30 minutes after the application to cure the resin and form a resin layer in grooves between neighboring circuit conductor parts. After that, the resulting printed wiring board was polished by buffing to remove the resin layer remaining on the top parts of the circuit conductor parts.

Next, for the resulting printed wiring board, a solder-resist film was formed using the above-mentioned water-based photosolder resist composition. The solder resist application was carried out by a screen-printing method.

### Example 2

As illustrated in FIG. 2, using a printed wiring board in which an etching resist film was left, a resin layer was formed in the same manner as the above-mentioned Example 1 to form a solder-resist film.

### Comparative Example 1

Using the same water-soluble photosolder resist composition as those of Examples 1 and 2 and without forming the resin layer unlike Example 1, a solder-resist film was formed by applying the water-soluble photosolder resist composition by a screen printing method in a manner that the composition covered the grooves between the neighboring circuit conductor parts and the top parts of the circuit conductor parts.

### Comparative Example 2

Ion-exchange water was added to the same water-soluble photosolder resist composition as those of Examples 1 and 2 to decrease the viscosity of the composition. Practically, ion-exchange water 9.5 parts by weight was added to the water-soluble photosolder resist composition 100 parts by weight, and using the obtained water-soluble photosolder resist composition, grooves between the neighboring circuit conductor parts and top parts of the circuit conductor parts were coated by an electrostatic spray coating method to form a solder-resist film for a printed wiring board similar to that of Example 1.

(Evaluation of Solder-Resist Film)

The solder-resist films of the printed wiring boards obtained in Examples 1 and 2 and Comparative Examples 1 and 2 were subjected to evaluation of the circuit conductor part-coating property and occurrence of foaming.

Coating property of the circuit conductor part was evaluated according to the following standards.

◯: the circuit conductor parts were completely coated with a solder-resist film:

Δ: the edge parts of the circuit conductor parts were not coated: and

×: the edge parts and the side face parts of the circuit conductor parts were not coated.

Occurrence of foaming in a solder-resist film was evaluated according to the following standards.

◯: no foam existed in a solder-resist film:

A: foams existed in a solder-resist film in the vicinity of the edge parts of the circuit conductor parts: and

×: foams exist in the entire area of a solder-resist film.

The evaluation results are shown in Table 1.

TABLE 1

| | | | Comp. | Comp. |
|---|---|---|---|---|
| | Ex. 1 | Ex. 2 | Ex. 1 | Ex. 2 |
| Coating Property of | ◯ | ◯ | X | Δ |
| the Circuit | | | | |
| Conductor Part | | | | |
| Foaming | ◯ | ◯ | X | ◯ |

As being made clear from Table 1, with respect to Examples 1 and 2 according to the present invention, it was found that the edge parts of the circuit conductor parts were coated excellently and that foams scarcely existed in the solder-resist films.

According to the present invention, a solder-resist film can be formed in a desirable state even on a circuit board having circuit conductor parts with a thick thickness.

What is claimed is:

1. A solder-resist film formation method for forming a solder-resist film on a circuit board having patterned circuit conductor parts at least on one face thereof, comprising the steps of
forming a resin layer between said neighboring circuit conductor parts by applying a liquid-phase curable resin so as to fill grooves between the neighboring circuit conductor parts and
forming a solder-resist film by applying a solder resist to the circuit board having the resin layer.

2. The solder-resist film formation method according to the claim 1, wherein the solder resist is a water-based solder resist.

3. The solder-resist film formation method according to the claim 1, wherein the thickness of the circuit conductor parts is 100 μm or thicker.

4. The solder-resist film formation method according to the claim 1, wherein the liquid-phase curable resin is applied so as to fill the grooves using only a squeegee without using a printing plate.

5. The solder-resist film formation method according to the claim 1, wherein the step of forming the resin layer includes a step of forming a resin layer by applying the liquid-phase curable resin and then curing the resin and a step of removing the resin layer remaining on the circuit conductor parts by polishing the surface of the circuit board.

6. The solder-resist film formation method according to the claim 5, wherein the solder resist is a water-based solder resist.

7. The solder-resist film formation method according to the claim 5, wherein the thickness of the circuit conductor parts is 100 μm or thicker.

8. The solder-resist film formation method according to the claim 5, wherein the liquid-phase curable resin is applied so as to fill the grooves using only a squeegee without using a printing plate.

9. A solder-resist film formation method for forming a solder-resist film on a circuit board having patterned circuit conductor parts at least on one face thereof, comprising the steps of
forming a resin layer by applying a liquid-phase curable resin to a circuit board in a state that an etching resist film used for patterning remains on circuit conductor parts, so as to fill grooves between the neighboring circuit conductor parts and curing the liquid-phase curable resin;
removing the etching resist film remaining on the surface of the circuit conductor parts together with the resin layer; and
forming a solder-resist film by applying a solder resist to the circuit board.

10. The solder-resist film formation method according to the claim 9, wherein the solder resist is a water-based solder resist.

11. The solder-resist film formation method according to the claim 9, wherein the thickness of the circuit conductor parts is 100 μm or thicker.

12. The solder-resist film formation method according to the claim 9, wherein the liquid-phase curable resin is applied so as to fill the grooves using only a squeegee without using a printing plate.
